(19) United States
(12) Patent Application Publication
(10) Pub. No.: US 2026/0299042 A1
(43) Pub. Date: Oct. 1, 2026

(54) BATTERY DIAGNOSTIC APPARATUS AND AN OPERATING METHOD THEREOF

(71) Applicants: HYUNDAI MOTOR COMPANY, Seoul (KR); KIA CORPORATION, Seoul (KR); Seoul National University R&DB Foundation, Seoul (KR)

(72) Inventors: Jun Hee Lee, Hwaseong-si (KR); In Woo Kim, Seoul (KR); Min Soo Kim, Seongnam-si (KR); Jang Wook Choi, Seoul (KR); Hyun Jae Kim, Seoul (KR)

(73) Assignees: HYUNDAI MOTOR COMPANY, Seoul (KR); KIA CORPORATION, Seoul (KR); Seoul National University R&DB Foundation, Seoul (KR)

(21) Appl. No.: 19/328,545

(22) Filed: Sep. 15, 2025

(30) Foreign Application Priority Data
Mar. 28, 2025 (KR) 10-2025-0040087

(51) Int. Cl. G01R 31/392; G01R 31/3835; G01R 31/396; H01M 10/42

(52) U.S. Cl. CPC G01R 31/392; G01R 31/3835; G01R 31/396; H01M 10/4285

(57) ABSTRACT

A battery diagnostic apparatus includes a memory configured to store at least one instruction and at least one processor configured, by executing the at least one instruction to obtain first voltage-capacity data and second voltage-capacity data measured in a charging and discharging process of a battery cell. The at least one processor may further determine kinetic dispersion defined as dispersion of a capacity difference between the first voltage-capacity data and the second voltage-capacity data. The at least one processor may further determine a state of the battery cell, based on the determined kinetic dispersion and a predetermined reference value related to the kinetic dispersion.

### CROSS-REFERENCE TO RELATED APPLICATION

This application claims the benefit of and priority to Korean Patent Application No. 10-2025-0040087, filed in the Korean Intellectual Property Office on Mar. 28, 2025, the entire contents of which are incorporated herein by reference.

### TECHNICAL FIELD

The present disclosure relates to a battery diagnostic apparatus and an operating method thereof.

### BACKGROUND

The electric vehicle (EV) industry is currently growing rapidly in response to global zero carbon emissions goals. Thus, the lithium-ion battery industry is also expanding rapidly. The development of the composition material and the manufacturing process of a battery cell plays an important role in the success of the lithium-ion battery industry. However, for sustainable growth, the operation characteristics of the cell according to the usage pattern and the environmental condition should be closely considered.

Particularly, it is important to accurately evaluate deterioration in battery cell. Because degradation in performance of the cell shows complex and unpredictable characteristics, this is becoming a technical challenge. A battery management system (BMS) uses various analysis tools and algorithms to evaluate the life and safety of the cell, but an existing electrochemical measurement method has a limitation in providing only fragmentary information and accurately predicting a sudden decrease in capacity of the battery.

The battery capacity deteriorates non-linearly over a charging/discharging period and time. Such a deterioration process is determined by complex chemical and electrochemical reactions in the cell. Thus, precisely understanding the non-linear behavior of the battery may provide important insights into diagnosing the current state of the battery and predicting the remaining life of the battery. The subject matter described in this background section is intended to promote an understanding of the background of the disclosure and thus may include subject matter that is not already known to those of ordinary skill in the art. The statements in this section merely provide background information related to the present disclosure and may not constitute prior art.

### SUMMARY

The present disclosure has been made to solve the above-mentioned problems occurring in the prior art while advantages achieved by the prior art are maintained intact.

An aspect of the present disclosure provides a battery diagnostic apparatus and an operating method thereof.

Another aspect of the present disclosure provides a battery diagnostic apparatus for diagnosing a non-linear degradation state a state of health (SOH) and a possibility of a sharp drop of the SOH, based on a diagnostic factor for reflecting a deterioration state in a battery cell, and an operating method thereof.

Another aspect of the present disclosure provides a battery diagnostic apparatus for diagnosing whether a waste battery is reusable or recyclable, based on a diagnostic factor for reflecting a deterioration state in a battery cell, and an operating method thereof.

The technical problems to be solved by the present disclosure are not limited to the aforementioned problems, and any other technical problems not mentioned herein should be clearly understood from the following description by those having ordinary skill in the art to which the present disclosure pertains.

According to an aspect of the present disclosure, a battery diagnostic apparatus may include a memory storing at least one instruction and at least one processor configured, by executing the at least one instruction, to obtain first voltage-capacity data and second voltage-capacity data measured in a charging and discharging process of a battery cell. The at least one processor may further determine kinetic dispersion defined as dispersion of a capacity difference between the first voltage-capacity data and the second voltage-capacity data. The at least one processor may further determine a state of the battery cell, based on the calculated kinetic dispersion and a predetermined reference value related to the kinetic dispersion.

In an embodiment, the first voltage-capacity data may include voltage-capacity data about high-rate charge, and the second voltage-capacity data may include voltage-capacity data about low-rate charge.

In an embodiment, the at least one processor may further calculate a state of health (SOH) degradation acceleration rate of the battery cell and may further set a reference value related to the SOH degradation acceleration rate used to determine a deterioration mode of the battery cell.

In an embodiment, the at least one processor may set the reference value related to the kinetic dispersion, based on a correlation between the SOH degradation acceleration rate and the kinetic dispersion.

In an embodiment, the at least one processor may further determine a deterioration mode of the battery cell and may further diagnose a possibility of a drop in a state of health (SOH) of the battery cell at or beyond a sharp drop point.

In an embodiment, the at least one processor may further determine the deterioration mode as a first deterioration mode in which SOH degradation of the battery cell accelerates at a first acceleration rate less than a predetermined reference acceleration rate, based on the determined kinetic dispersion being less than the predetermined reference value related to the kinetic dispersion, and may further diagnose that the possibility of the sharp drop is small. The at least one processor may further determine the deterioration mode as a second deterioration mode in which the SOH degradation of the battery cell accelerates at a second acceleration rate greater than or equal to the predetermined reference acceleration rate, based on the calculated kinetic dispersion being greater than or equal to the predetermined reference value related to the kinetic dispersion, and may further diagnose that the possibility of the sharp drop is large.

In an embodiment, the at least one processor may further diagnose whether the battery cell, an SOH of which is less than or equal to a certain value, is a reusable target or a recycle target.

In an embodiment, the at least one processor may further diagnose that the battery cell is the reusable target, based on the determined kinetic dispersion is less than the predetermined reference value related to the kinetic dispersion. The at least one processor may further diagnose that the battery cell is the recycle target, based on the determined kinetic dispersion is greater than or equal to the predetermined reference value related to the kinetic dispersion.

According to another aspect of the present disclosure, a battery diagnostic method may include obtaining first voltage-capacity data and second voltage-capacity data measured in a charging and discharging process of a battery cell. The method may further include determining kinetic dispersion defined as dispersion of a capacity difference between the first voltage-capacity data and the second voltage-capacity data. The method may further include determining a state of the battery cell, based on the determined kinetic dispersion and a predetermined reference value related to the kinetic dispersion.

In an embodiment, the first voltage-capacity data may include voltage-capacity data about high-rate charge, and the second voltage-capacity data may include voltage-capacity data about low-rate charge.

In an embodiment, the battery diagnostic method may further include calculating a state of health (SOH) degradation acceleration rate of the battery cell and setting a reference value related to the SOH degradation acceleration rate used to determine a deterioration mode of the battery cell.

In an embodiment, the battery diagnostic method may further include setting the reference value related to the kinetic dispersion, based on a correlation between the SOH degradation acceleration rate and the kinetic dispersion.

In an embodiment, determining the state of the battery cell may include determining a deterioration mode of the battery cell and diagnosing a possibility of a drop in a state of health (SOH) of the battery cell at or beyond a sharp drop point.

In an embodiment, determining the state of the battery cell may include determining the deterioration mode as a first deterioration mode in which SOH degradation of the battery cell accelerates at a first acceleration rate less than a predetermined reference acceleration rate, based on the determined kinetic dispersion being less than the predetermined reference value related to the kinetic dispersion, and diagnosing that the possibility of the sharp drop is small. Determining the state of the battery cell may further include determining the deterioration mode as a second deterioration mode in which the SOH degradation of the battery cell accelerates at a second acceleration rate greater than or equal to the predetermined reference acceleration rate, based on the determined kinetic dispersion being greater than or equal to the predetermined reference value related to the kinetic dispersion, and diagnosing that the possibility of the sharp drop is large.

In an embodiment, determining the state of the battery cell may include diagnosing whether the battery cell, an SOH of which is less than or equal to a certain value, is a reusable target or a recycle target.

In an embodiment, determining the state of the battery cell may include diagnosing that the battery cell is the reusable target, based on the determined kinetic dispersion being less than the predetermined reference value related to the kinetic dispersion. Determining the state of the battery cell may further include diagnosing that the battery cell is the recycle target, based on the determined kinetic dispersion being greater than or equal to the predetermined reference value related to the kinetic dispersion.

### BRIEF DESCRIPTION OF THE DRAWINGS

The above and other objects, features, and advantages of the present disclosure should be more apparent from the following detailed description taken in conjunction with the accompanying drawings:

FIG. 1 is a block diagram illustrating an example of an internal configuration of a battery diagnostic apparatus according to an embodiment of the present disclosure;

FIG. 2 is a drawing illustrating an example of state of health (SOH) data of a battery cell according to an embodiment of the present disclosure;

FIG. 3 is a drawing for describing a method for calculating an SOH degradation acceleration rate of a battery cell according to an embodiment of the present disclosure;

FIG. 4 is a drawing illustrating an example of voltage-capacity data of a battery cell according to an embodiment of the present disclosure;

FIG. 5 is a drawing illustrating an example of a capacity difference in a charging process of a battery cell according to an embodiment of the present disclosure;

FIG. 6 is a drawing for describing a correlation between an SOH degradation acceleration rate and kinetic dispersion of a battery cell according to an embodiment of the present disclosure;

FIG. 7 is a drawing for describing an example of a method for diagnosing a battery cell based on kinetic dispersion according to an embodiment of the present disclosure;

FIG. 8 is a drawing for describing another example of a method for diagnosing a battery cell based on kinetic dispersion according to an embodiment of the present disclosure;

FIG. 9 is a flowchart for describing an example of an operating method of a battery diagnostic apparatus according to an embodiment of the present disclosure; and

FIG. 10 is a drawing for describing an example of a computing system associated with a battery diagnostic apparatus or a battery diagnostic method according to an embodiment of the present disclosure.

### DETAILED DESCRIPTION

Hereinafter, some embodiments of the present disclosure are described in detail with reference to the drawings. In adding the reference numerals to the components of each drawing, it should be noted that the identical or equivalent components are designated by the identical numerals even when the components are displayed on other drawings. Further, in describing the embodiment of the present disclosure, a detailed description of well-known features or functions has been omitted in order not to unnecessarily obscure the gist of the present disclosure.

In describing components of embodiments of the present disclosure, the terms first, second, A, B, (a), (b), and the like may be used herein. These terms are only used to distinguish one component from another component, but do not limit the corresponding components irrespective of the order or priority of the corresponding components. Furthermore, unless otherwise defined, all terms including technical and scientific terms used herein have the same meaning as being generally understood by those having ordinary skill in the art to which the present disclosure pertains. Such terms as those defined in a generally used dictionary should be interpreted as having meanings equal to the contextual meanings in the relevant field of art and should not be interpreted as having ideal or excessively formal meanings unless clearly defined as having such in the present disclosure.

Furthermore, in the present disclosure, the expression “greater than” or “less than” is used to determine whether a specific condition is satisfied or fulfilled, is only to represent an example, and does not exclude the expression “greater than or equal to” or “less than or equal to”. A condition described as being “greater than or equal to” may be replaced with a condition described as being “greater than”, a condition describing as being “less than or equal to” may be replaced with a condition described as being “less than”, and a condition described as being “greater than or equal to and less than” may be replaced with “greater than and less than or equal to”. Furthermore, hereinafter, “A” and “B” refer to at least one of components from A (including A) to B (including B).

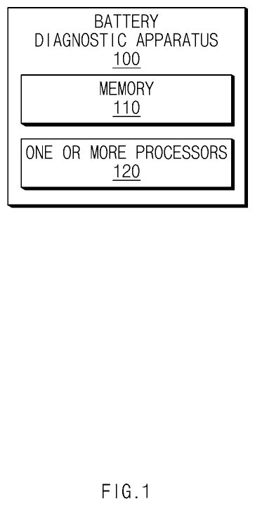

Hereinafter, embodiments of the present disclosure are described in detail with reference to FIGS. 1-10.

FIG. 1 is a block diagram illustrating an example of an internal configuration of a battery diagnostic apparatus according to an embodiment of the present disclosure.

Referring to FIG. 1, a battery diagnostic apparatus 100 may include a memory 110 and one or more processors 120. The memory 110 may store at least one instruction. The one or more processors 120 may execute the at least one instruction.

According to an embodiment, the battery diagnostic apparatus 100 may be included in a battery management system (BMS) or may be configured as a system different from the BMS.

According to an embodiment, the battery diagnostic apparatus 100 may be included in a battery pack configured to include a battery unit, a sensor device, and the BMS. For example, the battery unit may refer to a component, which is electrically connected to a target device to supply power. Herein, the target device may include an electrical, electronic, or mechanic device for operating by receiving power from the battery pack. For example, the target device may be, but is not limited to, an electric vehicle (EV). According to an embodiment, the battery unit may be a battery cell or a battery bank. For example, the battery cell may be, but is not limited to, a lithium-ion (Li-ion) battery, a lithium-ion (Li-ion) polymer battery, a nickel cadmium (Ni-Cd) battery, a nickel hydrogen (Ni-MH) battery, or the like. The sensor device may refer to a component for obtaining values associated with a state of the battery unit. For example, the values associated with the state of the battery unit may include one or more values for a voltage, a current, resistance, a state of charge (SOC), a state of health (SOH), or a temperature, or any combination thereof. The BMS may refer to a component for controlling or managing the battery pack. According to an embodiment, the operation of the battery diagnostic apparatus 100 below may be performed by the BMS.

According to an embodiment, the battery diagnostic apparatus 100 may be configured as another device outside the battery pack. For example, the battery diagnostic apparatus 100 may be configured to be included in various devices, such as a server, a cloud, a charger, or a charger/discharger outside the battery pack. According to an embodiment, the battery diagnostic apparatus 100 may be connected to the battery pack in a wireless or wired communication scheme to transmit and receive information. According to an embodiment, the operation of the battery diagnostic apparatus 100 below may be performed in the various devices, such as the server, the cloud, the charger, or the charger/discharger.

Meanwhile, the memory 110 may store at least some of pieces of data processed by the battery diagnostic apparatus 100.

According to various embodiments, the memory 110 may store SOH data of the battery cell. Furthermore, the memory 110 may store voltage-capacity data measured in a charging and discharging process of the battery cell.

According to an embodiment, the memory 110 may store at least some of reference values used for the battery diagnosis method. For example, the reference value preset by the one or more processors 120 may be stored in the memory 110. For example, the reference value may include a reference value related to an SOH degradation acceleration rate and a reference value related to kinetic dispersion.

According to an embodiment, the one or more processors 120 may obtain first voltage-capacity data and second voltage-capacity data measured in the charging and discharging process of the battery cell and may calculate kinetic dispersion defined as dispersion of a capacity difference between the first voltage-capacity data and the second voltage-capacity data.

According to an embodiment, the one or more processors 120 may diagnose a state of the battery cell, based on the kinetic dispersion and a predetermined reference value related to the kinetic dispersion. According to an embodiment, the one or more processors 120 may calculate an SOH degradation acceleration rate of the battery cell to set the predetermined reference value related to the kinetic dispersion, may set a reference value about the SOH degradation acceleration rate, and may analyze a correlation between the SOH degradation acceleration rate and the kinetic dispersion.

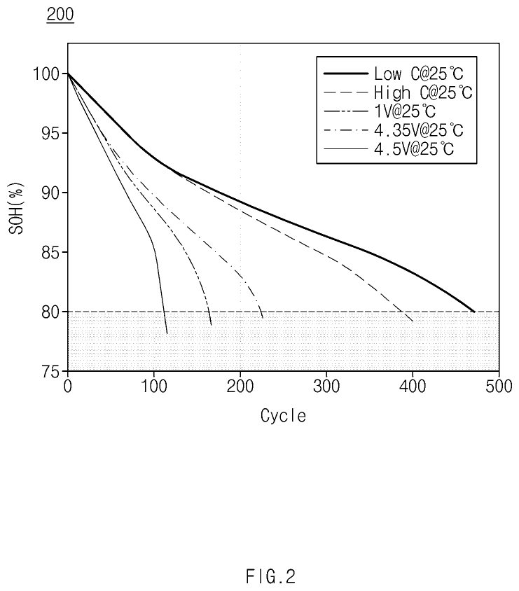

Hereinafter, operations respectively performed by the components included in the battery diagnostic apparatus 100 shown in FIG. 1 are described in detail with reference to FIGS. 2-8.

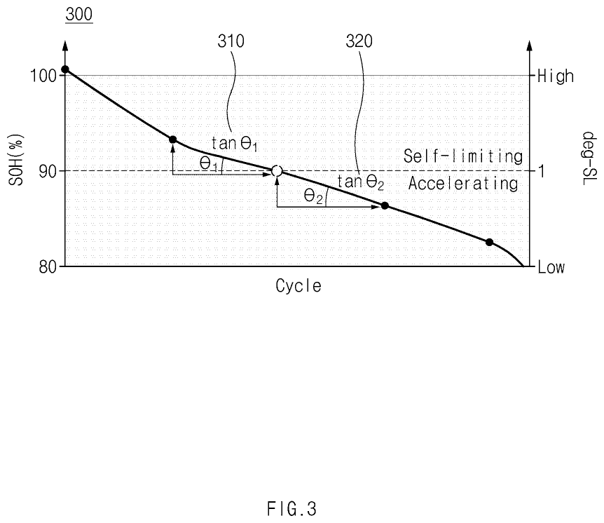

FIG. 2 is a drawing illustrating an example of SOH data of a battery cell. FIG. 3 is a drawing for describing a method for calculating an SOH degradation acceleration rate of a battery cell according to an embodiment of the present disclosure.

Referring to FIG. 2, one or more processors 120 may obtain SOH data of a battery cell. According to an embodiment, the SOH data may be data about a change in SOCH according to a charge/discharge cycle of the battery cell. For example, graph data 200 indicating a relationship between the charge/discharge cycle and the SOH of the battery cell is illustrated as an example of the SOH data of the battery cell.

For example, the graph data 200 may include one or more graphs in which the SOH is non-linearly degraded according to the use of the battery cell in various use conditions. For example, each of the one or more graphs may correspond to non-linear SOH degradation remodeling of a lithium nickel cobalt aluminum oxide (NCA)/graphite-silicon (Gr-Si) cell. The use condition of the battery cell may include a temperature, a voltage, a charge/discharge rate, or the like. For example, each of the one or more graphs may correspond to a different voltage (V) condition or a different charge/discharge rate (C) condition as shown in FIG. 2.

Herein, that the SOH is non-linearly degraded may mean that the slope at which the SOH is degraded differs for each time point (or each cycle) when the SOH is measured. For example, referring to the graph data 200 shown in FIG. 2, the SOH of the battery cell may show a tendency to be relatively slowly reduced at an initial cycle and be sharply degraded after a specific cycle. For example, that the SOH is sharply degraded at the specific cycle may be understood as one of sharp drop phenomena of the battery cell. The specific cycle may be referred to as a sharp drop point. In the present disclosure, that the SOH of the battery cell is non-linearly degraded may be analyzed as a quantitative index, such as an SOH degradation acceleration rate.

According to an embodiment, a battery cell, the SOH of which decreases to 80% or less (or less than 80% in some embodiments) on the graph data 200 may be classified as a waste battery. For example, as shown in FIG. 2, the number of cycles at which the SOH decreases to 80% or less may vary with the use condition.

Referring to FIG. 3, graph data 300 including some of pieces of SOH data of the battery cell is illustrated.

In an embodiment, the one or more processors 120 may calculate an SOH degradation acceleration rate (1/deg-SL) of the battery cell based on the SOH data. For example, the one or more processors 120 may calculate the SOH degradation acceleration rate based on a ratio between SOH degradation slopes of one interval and another interval included in the SOH data. For example, the one or more processors 120 may calculate the SOH degradation acceleration rate based on a value obtained by dividing an SOH degradation slope 320 in an interval after a certain cycle from a reference point (or a measurement point) by an SOH degradation slope 310 in an interval before the certain cycle from the reference point. For example, the SOH degradation slope 310 and the SOH degradation slope 320 may be calculated based on a slope between both endpoints, as shown in FIG. 3. As another example, each of the SOH degradation slope 310 and the SOH degradation slope 320 may be calculated based on an average slope. For example, the SOH degradation slope 310 may be an average SOH degradation slope in the interval before the certain cycle from the reference point.

In an embodiment, the one or more processors 120 may determine a deterioration mode of the battery cell based on the SOH degradation acceleration rate. For example, when the SOH degradation acceleration rate is less than a reference value about the SOH degradation acceleration rate, the one or more processors 120 may determine the deterioration mode as a first deterioration mode (Self-limiting) in which SOH degradation of the battery cell gently accelerates. In other words, as the SOH degradation slope 310 in the interval before the certain cycle from the reference point has a value greater than the SOH degradation slope 320 in the interval after the certain cycle from the reference point, the SOH degradation acceleration rate may be calculated as a small value. As a result, it may be understood that the SOH degradation of the battery cell gently accelerates (e.g., the SOH degradation of the battery cell accelerates at a first acceleration rate less than a predetermined reference acceleration rate). For another example, when the SOH degradation acceleration rate is greater than or equal to the reference value about the SOH degradation acceleration rate, the one or more processors 120 may determine the deterioration mode as a second deterioration mode (Accelerating) in which SOH degradation of the battery cell sharply accelerates. In other words, as the SOH degradation slope 320 in the interval after the certain cycle from the reference point has a value greater than the SOH degradation slope 310 in the interval before the certain cycle from the reference point, the SOH degradation acceleration rate may be calculated as a large value. As a result, it may be understood that the SOH degradation of the battery cell sharply accelerates (e.g., the SOH degradation of the battery cell accelerates at a second acceleration rate greater than or equal to the predetermined reference acceleration rate). Meanwhile, deg-SL shown in FIG. 3 may refer to a reciprocal of the SOH degradation acceleration rate.

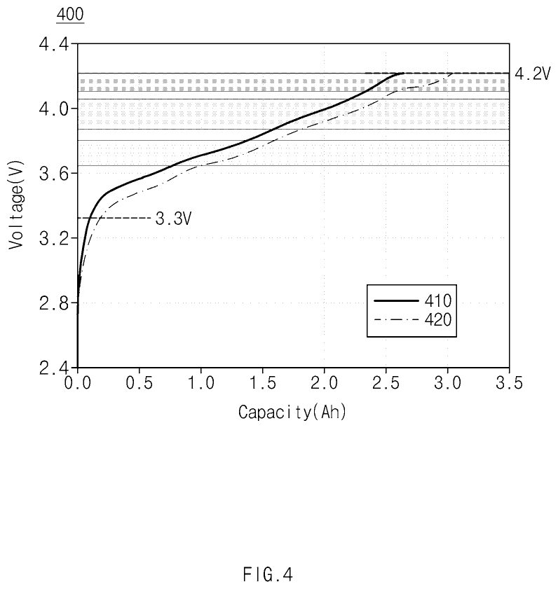

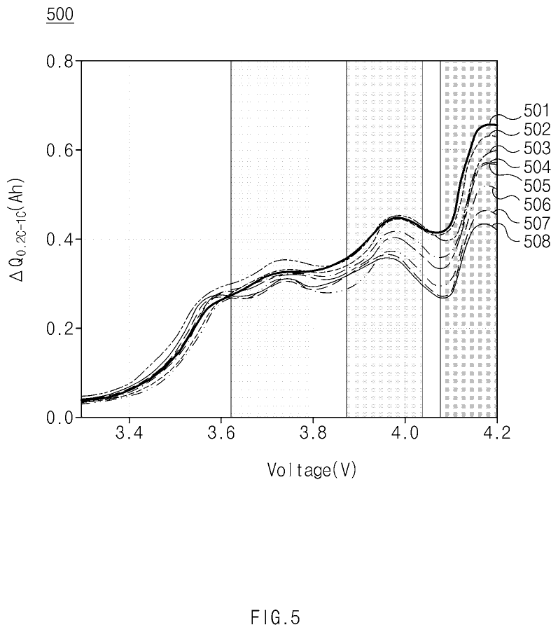

FIG. 4 is a drawing illustrating an example of voltage-capacity data of a battery cell according to an embodiment of the present disclosure. FIG. 5 is a drawing illustrating an example of a capacity difference in a charging process of a battery cell according to an embodiment of the present disclosure.

Referring to FIG. 4, one or more processors 120 may obtain voltage-capacity data measured in a charging and discharging process of a battery cell. A voltage-capacity graph 400 measured in the charging process of the battery cell is illustrated as an example of the voltage-capacity data. For example, the voltage-capacity graph 400 may indicate a relationship between a voltage measured in the process of charging the battery cell and the charged capacity. The voltage-capacity graph 400 is not limited to the example shown in FIG. 4. The charged capacity may be represented as SOC (%). For example, remodeling of the voltage-capacity graph 400 may vary with various use conditions (e.g., a charge/discharge rate, a voltage, a current, resistance, a temperature, density, humidity, and the like) of the battery cell.

In an embodiment, voltage-capacity data may include first voltage-capacity data 410 about high-rate charge and second voltage-capacity data 420 about low-rate charge. For example, the first voltage-capacity data 410 may be data corresponding to a charge rate of 1 C and the second voltage-capacity data 420 may be data corresponding to a charge rate of 0.2 C. However, a detailed numerical value of a charge rate corresponding to each of the high-rate charge and the low-rate charge is not limited thereto. Meanwhile, the first voltage-capacity data 410 and the second voltage-capacity data 420 may have the same other use conditions (e.g., a voltage, a current, resistance, a temperature, density, humidity, and the like) except for the charge/discharge rate.

Referring to FIG. 4, the first voltage-capacity data 410 and the second voltage-capacity data 420 may vary in slope about a voltage rise in an interval in which the voltage sharply rises. Furthermore, in the first voltage-capacity data 410 and the second voltage-capacity data 420, maximum charging capacity may vary and a slope at which it is charged to the maximum charging capacity and a time taken to be charged to the maximum charging capacity may vary.

Other than the above-mentioned differences, the first voltage-capacity data 410 and the second voltage-capacity data 420 may have various non-linear differences. Such differences about non-linearity may be due to internal deterioration in the battery cell. For example, as the internal deterioration in the battery cell proceeds, the first voltage-capacity data 410 may have a charging curve, which more moves to the left than the second voltage-capacity data 420. This may mean that chargeable capacity is degraded. Because a charging curve corresponding to a high-rate charge among charging curves is able to well show non-uniformity in the battery cell, as a difference between the charging curve (e.g., the first voltage-capacity data 410) corresponding to the high-rate charge and a charging curve (e.g., the second voltage-capacity data 420) corresponding to a low-rate charge is larger, deterioration in the battery cell may more proceed. In the present disclosure, a deterioration degree in the battery cell may be analyzed, using a quantitative index, such as kinetic dispersion calculated based on the capacity difference.

Meanwhile, each of the first voltage-capacity data 410 and the second voltage-capacity data 420 may be measured or obtained at a certain period. For example, a period when the first voltage-capacity data 410 is measured, and a period when the second voltage-capacity data 420 is measured may differ from each other.

In an embodiment, the one or more processors 120 may obtain the first voltage-capacity data 410 or the second voltage-capacity data 420 measured in a charging process, which is closest to a time point when the state of the battery cell is diagnosed.

Meanwhile, voltage-capacity data may include voltage-capacity data measured in a discharging process. For example, the discharging curve may indicate a relationship between a voltage when the battery cell and discharge capacity are discharged. For example, the discharge capacity may be represented as SOC (%). In an embodiment, the voltage-capacity data measured in the discharging process may include voltage-capacity data about high-rate discharge and voltage-capacity data about low-rate discharge. Hereinafter, for convenience of description, a description is given of an embodiment of using the voltage-capacity data measured in the charging process. The embodiment described in the present disclosure may also be applied to an embodiment of using the voltage-capacity data measured in the discharging process.

Referring to FIG. 5, graph data 500 including a plurality of graphs 501 to 508 illustrating a change in capacity difference is illustrated. For example, each of the plurality of graphs 501-508 may illustrate a change in capacity difference calculated based on two pieces of different voltage-capacity data. Herein, the two pieces of different voltage-capacity data may be selected among pieces of voltage-capacity data measured in the charging and discharging process of the battery.

For example, referring to the graph data 500, the change in capacity difference may be represented based on a voltage. In other words, the capacity difference may be calculated based on the same voltage in the two pieces of different voltage-capacity data. For example, the graph data 500 may include the plurality of graphs 501-508 illustrating a change in capacity difference of the battery cell, which is calculated based on various use conditions.

In an embodiment, the one or more processors 120 may calculate a change in capacity difference, based on the first voltage-capacity data 410 about the high-rate charge and the second voltage-capacity data 420 about the low-rate charge. In an embodiment, the one or more processors 120 may calculate the change in capacity difference, based on the first voltage-capacity data 410 and the second voltage-capacity data 420, which have the same other use conditions, except for a charge/discharge rate. For example, the change in capacity difference between the first voltage-capacity data 410 and the second voltage-capacity data 420 may be represented as any one of the plurality of graphs 501 to 508 included in the graph data 500. For example, each of the plurality of graphs 501-508 included in the graph data 500 may correspond to a different use condition. For example, each of the plurality of graphs 501-508 may be a graph illustrating a change in capacity difference between a high-rate charging curve and a low-rate charging curve, which are measured at different temperatures.

According to an embodiment, the one or more processors 120 may calculate kinetic dispersion based on the capacity difference in the charging and discharging process of the battery cell. For example, the kinetic dispersion may be a factor used to diagnose a state of the battery cell.

In an embodiment, the one or more processors 120 may calculate the kinetic dispersion, based on the first voltage-capacity data 410 about the high-rate charge and the second voltage-capacity data 420 about the low-rate charge.

In the present disclosure, the kinetic dispersion may be understood as dispersion for reflecting a kinetic characteristic of the battery cell, which occurs due to chemical and electrochemical phenomena in the battery cell (e.g., diffusion of lithium ions, a reaction velocity of the electrode, resistance in the delivery process of charges, or the like). In another aspect, the present disclosure may digitalize a deterioration state in the battery cell using the kinetic dispersion.

In an embodiment, the kinetic dispersion may be defined as dispersion of the capacity difference between the two pieces of different voltage-capacity data. For example, the one or more processors 120 may calculate the kinetic dispersion, based on the dispersion of the capacity difference between the first voltage-capacity data 410 about the high-rate charge and the second voltage-capacity data 420 about the low-rate charge. In detail, the one or more processors 120 may calculate capacity differences based on each of the same voltages in the first voltage-capacity data 410 about the high-rate charge and the second voltage-capacity data 420 about the low-rate charge and may calculate dispersion of the capacity differences using a certain equation. As described above, because the charging curve corresponding to the high-rate charge is able to well show non-uniformity in the battery cell, the capacity difference between the charging curve corresponding to the high-rate charge and the charging curve corresponding to the low-rate charge may be understood as a factor for suitably reflecting a deterioration state in the battery cell. Meanwhile, as the equation for calculating dispersion is apparent to those having ordinary skill in the art, a description thereof has been omitted in the present disclosure.

Meanwhile, referring to FIG. 5, the one or more processors 120 may calculate kinetic dispersion for each of the graphs 501-508 included in the graph data 500.

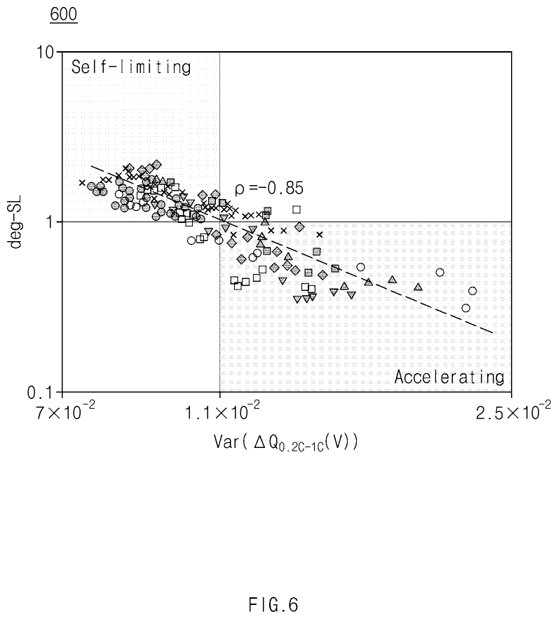

FIG. 6 is a drawing for describing a correlation between an SOH degradation acceleration rate and kinetic dispersion of a battery cell according to an embodiment of the present disclosure.

In an embodiment, a reference value related to the SOH degradation acceleration rate of the battery cell may be set to 1. For example, a deterioration mode of a target battery cell may be determined via comparison between an SOH degradation acceleration rate of the target battery cell and the reference value (e.g., 1). Herein, the target battery cell may refer to a battery cell, which is targeted at state diagnosis.

Referring to FIG. 6, when the SOH degradation acceleration rate of the target battery cell is less than 1 (when a deg-SL value, which is a reciprocal of the SOH degradation acceleration rate, is greater than 1), one or more processors 120 may determine the deterioration mode as a first deterioration mode (Self-limiting) in which SOH degradation of the battery cell gently accelerates. Alternatively, when the SOH degradation acceleration rate is greater than or equal to 1 (when the deg-SL value, which is the reciprocal of the SOH degradation acceleration rate, is less than or equal to 1), the one or more processors 120 may determine the deterioration mode as a second deterioration mode (Accelerating) in which SOH degradation of the battery cell sharply accelerates.

Meanwhile, it may be checked that the contribution of the anode of the battery cell is greater than the contribution of the cathode of the battery cell in non-linearity of SOH degradation of the battery cell via a certain experiment. For example, it may be checked that a loss of active material (LAM), which is one of cell deterioration phenomena mainly occurring in the cathode, and an SOH degradation acceleration rate do have a significant association. On the other hand, it may be checked that lithium deposition, which is one of cell deterioration phenomena mainly occurring in the anode, has a significant association with the SOH degradation acceleration rate. For example, a correlation between the LAM in the cathode and the SOH degradation acceleration rate may not be large, but the lithium deposition in the anode may indicate a positive correlation with the SOH degradation acceleration rate.

Furthermore, deterioration in the anode may be better reflected in a charging curve of the battery than a discharging curve of the battery. This is because lithium ions move from the cathode to the anode in the charging process of the battery. In the present disclosure, based on it, the correlation between the kinetic dispersion in the charging curve capable of numerically well reflecting deterioration in the anode and the SOH degradation acceleration rate with an association with deterioration in the anode is checked via the experiment.

It may be checked via a graph 600 illustrating the correlation between the SOH degradation acceleration rate and the kinetic dispersion shown in FIG. 6. The SOH degradation acceleration rate and the kinetic dispersion may have a proportional relationship (an inversely proportional relationship with the reciprocal deg-SL of the SOH degradation acceleration rate). In other words, as a result of calculating kinetic dispersion of a target battery cell, the SOH degradation acceleration rate may be larger as the kinetic dispersion value is larger and the SOH degradation acceleration rate may be smaller as the kinetic dispersion value is smaller.

Meanwhile, the one or more processors 120 may set a reference value related to the kinetic dispersion based on the correlation between the SOH degradation acceleration rate and the kinetic dispersion. For example, the one or more processors 120 may set the reference value related to the kinetic dispersion, based on data (e.g., the graph 600) obtained by matching the SOH degradation acceleration rate and the kinetic dispersion of the battery cell. For example, based on that the kinetic dispersion of the battery cell, the SOH degradation acceleration rate of which is calculated as 1, is calculated as a value similar to a specific value (e.g., 0.011), the one or more processors 120 may set the specific value (e.g., 0.011) to the reference value related to the kinetic dispersion. In other words, the reference value related to the kinetic dispersion may be set to a value with the largest association with the reference value related to the SOH degradation acceleration rate of the battery cell. Meanwhile, the reference value related to the SOH degradation acceleration rate of the battery cell may be a setting value changeable by a user.

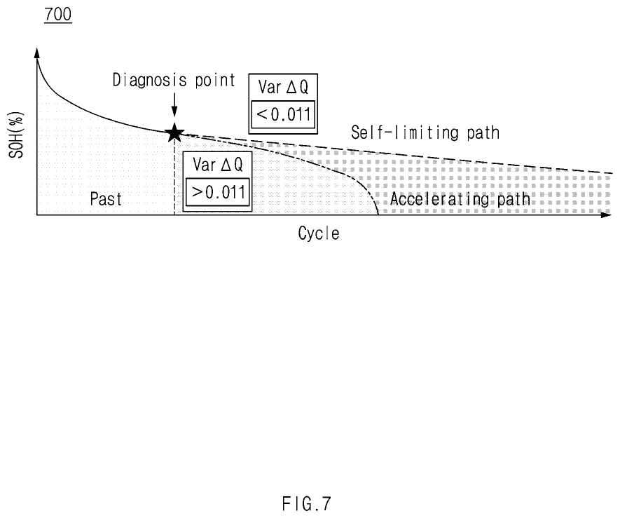

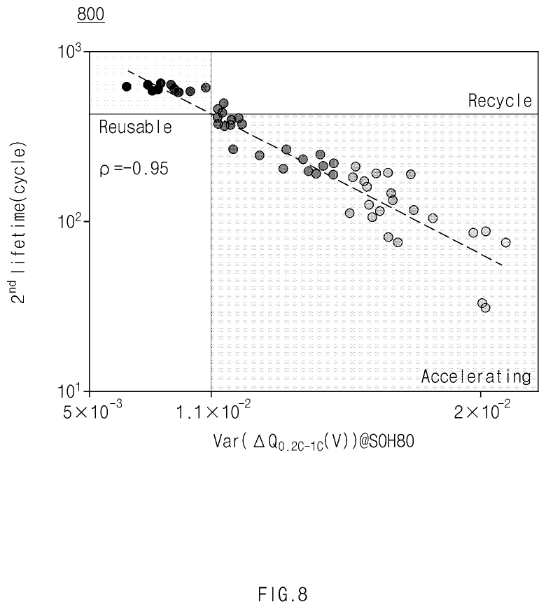

FIG. 7 is a drawing for describing an example of a method for diagnosing a battery cell based on kinetic dispersion according to an embodiment of the present disclosure. FIG. 8 is a drawing for describing another example of a method for diagnosing a battery cell based on kinetic dispersion according to an embodiment of the present disclosure.

In an embodiment, one or more processors 120 may diagnose a state of a battery, based on kinetic dispersion of a target battery cell and a reference value related to the kinetic dispersion.

To sum up, the one or more processors 120 in the present disclosure may calculate a factor for diagnosing a state of a battery cell using data about at least one battery cell, may set a reference value about the factor, and may compare a factor of the target battery cell with the reference value to diagnose a state of the target battery cell.

In an embodiment, the one or more processors 120 may determine a deterioration mode of the target battery cell, based on data of the target battery cell and may diagnose a possibility a sharp drop of the SOH of the target battery cell.

Referring to FIG. 7, the one or more processors 120 may determine the deterioration mode of the target battery cell, via comparison between kinetic dispersion of the target battery cell and the reference value, and may diagnose the possibility of the sharp drop of the SOH of the target battery cell.

For example, when the kinetic dispersion of the target battery cell is less than the reference value (e.g., 0.011) related to the kinetic dispersion, the one or more processors 120 may determine that the deterioration mode of the target battery cell is as a first deterioration mode (Self-limiting) in which SOH degradation gently accelerates. Furthermore, the one or more processors 120 may diagnose that the possibility of the sharp drop of the target battery cell is small.

For another example, when the kinetic dispersion of the target battery cell is greater than or equal to the reference value (e.g., 0.011) related to the kinetic dispersion, the one or more processors 120 may determine that the deterioration mode of the target battery cell is as a second deterioration mode (Accelerating) in which the SOH degradation sharply accelerates. Furthermore, the one or more processors 120 may diagnose that the possibility of the sharp drop of the target battery cell is large.

In an embodiment, the one or more processors 120 may diagnose whether the target battery cell is a reusable or recycle target, based on data of the target battery cell.

Referring to FIG. 8, a graph 800 illustrating a correlation between kinetic dispersion and second life of a waste battery is illustrated. Herein, the waste battery may refer to a battery, the SOH of which is less than or equal to a certain value. For example, the battery, the SOH of which is less than or equal to 80%, may be classified as the waste battery.

Referring to the graph 800, it is illustrated that kinetic dispersion of the battery cell has a negative correlation (e.g., an inversely proportional relation) with the second life of the waste battery. Herein, the second life of the waste battery may refer to life of the battery after the SOH drops to a certain value or less. In the present disclosure, because the kinetic dispersion of the battery cell has an association with the second life of the waste battery, the one or more processors 120 may diagnose whether the target battery cell is a reusable target or a recycle target of the waste battery using the kinetic dispersion of the target battery cell.

For example, because the second life of the target battery cell is able to be smaller as the kinetic dispersion of the target battery cell is calculated as a larger value, the one or more processors 120 may diagnose that the target battery cell is the recycle target. For another example, because the second life of the target battery cell is able to be larger as the kinetic dispersion of the target battery cell is calculated as a smaller value, the one or more processors 120 may diagnose that the target battery cell is the reusable target. Herein, the reference value related to the kinetic dispersion may also be used to diagnose whether the target battery cell is the reusable or recycle target. For example, the one or more processors 120 may diagnose whether a target battery (herein, referring to a waste battery) is a reusable or recycle target via comparison between the kinetic dispersion of the target battery cell and the reference value (e.g., 0.011).

Meanwhile, the reusability of the waste battery may mean that the waste battery is reused as a battery. In some embodiments, a purpose in which the waste battery is used in the process in which the waste battery is reused may vary. The recycling of the waste battery may refer to that metal or some raw materials are extracted and disassembled. In some embodiments, materials extracted in the recycling process of the waste battery may be used to manufacture a new battery.

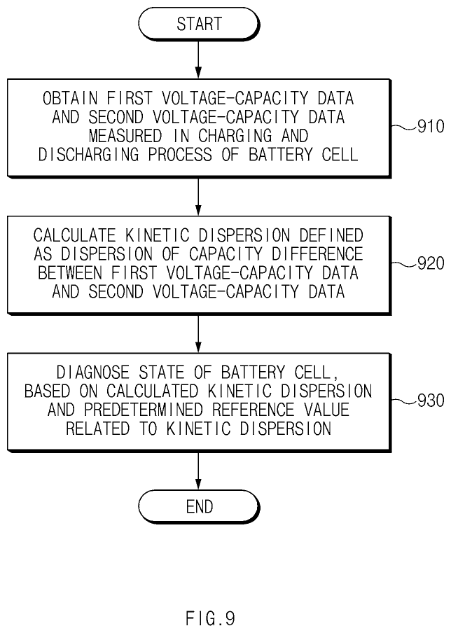

FIG. 9 is a flowchart for describing an example of an operating method of a battery diagnostic apparatus according to an embodiment of the present disclosure.

Referring to FIG. 9, in operation 910, one or more processors 120 may obtain first voltage-capacity data and second voltage-capacity data measured in a charging and discharging process of a battery cell.

In an embodiment, the first voltage-capacity data may include voltage-capacity data about high-rate charge, and the second voltage-capacity data may include voltage-capacity data about low-rate charge.

Meanwhile, in operation 920, the one or more processors 120 may calculate kinetic dispersion defined as dispersion of a capacity difference between the first voltage-capacity data and the second voltage-capacity data.

Meanwhile, in operation 930, the one or more processors 120 may diagnose a state of the battery cell, based on the calculated kinetic dispersion and a predetermined reference value related to the kinetic dispersion.

In an embodiment, the one or more processors 120 may calculate an SOH degradation acceleration rate of the battery cell and may a reference value related to the SOH degradation acceleration rate used to determine a deterioration mode of the battery cell.

In an embodiment, the one or more processors 120 may set the predetermined reference value related to the kinetic dispersion based on a correlation between the SOH degradation acceleration rate and the kinetic dispersion.

In an embodiment, the one or more processors 120 may determine the deterioration mode of the target battery cell and may diagnose a possibility a sharp drop of an SOH of the battery cell.

In an embodiment, when the calculated kinetic dispersion is less than the predetermined reference value related to the kinetic dispersion, the one or more processors 120 may determine the deterioration mode as a first deterioration mode in which SOH degradation of the battery cell gently accelerates, and the one or more processors 120 may diagnose that a possibility of a sharp drop is small. Alternatively, when the calculated kinetic dispersion is greater than or equal to the predetermined reference value related to the kinetic dispersion, the one or more processors 120 may determine the deterioration mode as a second deterioration mode in which the SOH degradation of the battery cell sharply accelerates, and the one or more processors 120 may diagnose that the possibility of the sharp drop is large.

In an embodiment, the one or more processors 120 may diagnose whether a battery cell, the SOH of which is less than or equal to a certain value, is a reusable target or a recycle target.

In an embodiment, when the calculated kinetic dispersion is less than the predetermined reference value related to the kinetic dispersion, the one or more processors 120 may diagnose that the battery cell is the reusable target. Alternatively, when the calculated kinetic dispersion is greater than or equal to the predetermined reference value related to the kinetic dispersion, the one or more processors 120 may diagnose that the battery cell is the recycle target.

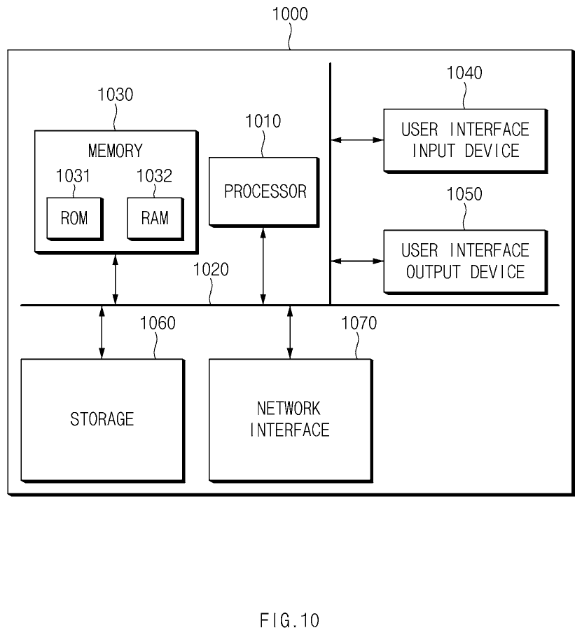

FIG. 10 is a drawing for describing an example of a computing system associated with a battery diagnostic apparatus or a battery diagnostic method according to an embodiment of the present disclosure.

Referring to FIG. 10, a computing system 1000 may include at least one processor 1010, a memory 1030, a user interface input device 1040, a user interface output device 1050, a storage 1060, and a network interface 1070, which are connected to each other via a bus 1020.

The processor 1010 may be a central processing unit (CPU) or a semiconductor device that processes instructions stored in the memory 1030 and/or the storage 1060. The memory 1030 and the storage 1060 may include various types of volatile or non-volatile storage media. For example, the memory 1030 may include a read only memory (ROM) 1031 and a random access memory (RAM) 1032.

Accordingly, the operations of the method or algorithm described in connection with the embodiments disclosed in the specification may be directly implemented with a hardware module, a software module, or a combination of the hardware module and the software module, which is executed by the processor 1010. The software module may reside on a storage medium (i.e., the memory 1030 and/or the storage module 1060) such as a RAM, a flash memory, a ROM, an EPROM, an EEPROM, a register, a hard disc, a removable disk, and a CD-ROM.

The storage medium may be coupled to the processor 1010. The processor 1010 may read out information from the storage medium and may write information in the storage medium. Alternatively, the storage medium may be integrated with the processor 1010. The processor and the storage medium may reside in an application specific integrated circuit (ASIC). The ASIC may reside within a user terminal. In another case, the processor and the storage medium may reside in the user terminal as separate components.

According to an embodiment of the present disclosure, the battery diagnostic apparatus may diagnose a non-linear degradation state a state of health (SOH) and a possibility of a sharp drop of the SOH, based on a diagnostic factor for reflecting a deterioration state in a battery cell.

According to an embodiment of the present disclosure, the battery diagnostic apparatus may diagnose whether a waste battery is reusable or recyclable, based on the diagnostic factor for reflecting the deterioration state in the battery cell.

In addition, various effects ascertained directly or indirectly through the present disclosure may be provided.

Hereinabove, although the present disclosure has been described with reference to embodiments and the accompanying drawings, the present disclosure is not limited thereto but may be variously modified and altered by those having ordinary skill in the art to which the present disclosure pertains without departing from the spirit and scope of the present disclosure claimed in the following claims.

Therefore, embodiments of the present disclosure are not intended to limit the technical spirit of the present disclosure, but provided only for the illustrative purpose. The scope of the present disclosure should be construed based on the accompanying claims, and all the technical ideas within the scope equivalent to the claims should be included in the scope of the present disclosure.

What is claimed is:

1. A battery diagnostic apparatus, comprising:
a memory configured to store at least one instruction; and
at least one processor configured, by executing the at least one instruction, to:
obtain first voltage-capacity data and second voltage-capacity data measured in a charging and discharging process of a battery cell;
determine a kinetic dispersion, defined as a dispersion of a capacity difference between the first voltage-capacity data and the second voltage-capacity data; and
determine a state of the battery cell, based on the determined kinetic dispersion and a predetermined reference value associated with the kinetic dispersion.

2. The battery diagnostic apparatus of claim 1, wherein the first voltage-capacity data includes voltage-capacity data about high-rate charge, and
wherein the second voltage-capacity data includes voltage-capacity data about low-rate charge.

3. The battery diagnostic apparatus of claim 1, wherein the at least one processor is further configured to:
calculate a state of health (SOH) degradation acceleration rate of the battery cell; and
set a reference value related to the SOH degradation acceleration rate used to determine a deterioration mode of the battery cell.

4. The battery diagnostic apparatus of claim 3, wherein the at least one processor is further configured to:
set the reference value related to the kinetic dispersion, based on a correlation between the SOH degradation acceleration rate and the kinetic dispersion.

5. The battery diagnostic apparatus of claim 1, wherein the at least one processor is configured to:
determine a deterioration mode of the battery cell; and
diagnose a possibility of a drop in a state of health (SOH) of the battery cell at or beyond a sharp drop point.

6. The battery diagnostic apparatus of claim 5, wherein the at least one processor is configured to:
determine the deterioration mode as a first deterioration mode in which SOH degradation of the battery cell accelerates at a first acceleration rate less than a predetermined reference acceleration rate, based on the determined kinetic dispersion being less than the predetermined reference value related to the kinetic dispersion, and diagnose that the possibility of the drop is small; and
determine the deterioration mode as a second deterioration mode in which the SOH degradation of the battery cell accelerates at a second acceleration rate greater than or equal to the predetermined reference acceleration rate, based on the determined kinetic dispersion being greater than or equal to the predetermined reference value related to the kinetic dispersion, and diagnose that the possibility of the drop is large.

7. The battery diagnostic apparatus of claim 1, wherein the at least one processor is configured to:
diagnose whether the battery cell, an SOH of which is less than or equal to a certain value, is a reusable target or a recycle target.

8. The battery diagnostic apparatus of claim 7, wherein the at least one processor is configured to:
diagnose that the battery cell is the reusable target, based on the determined kinetic dispersion being less than the predetermined reference value related to the kinetic dispersion; and
diagnose that the battery cell is the recycle target, based on the determined kinetic dispersion being greater than or equal to the predetermined reference value related to the kinetic dispersion.

9. A battery diagnostic method, comprising:
obtaining first voltage-capacity data and second voltage-capacity data measured in a charging and discharging process of a battery cell;
determining kinetic dispersion defined as dispersion of a capacity difference between the first voltage-capacity data and the second voltage-capacity data; and
determining a state of the battery cell, based on the determined kinetic dispersion and a predetermined reference value related to the kinetic dispersion.

10. The battery diagnostic method of claim 9, wherein the first voltage-capacity data includes voltage-capacity data about high-rate charge, and
wherein the second voltage-capacity data includes voltage-capacity data about low-rate charge.

11. The battery diagnostic method of claim 9, further comprising:
calculating a state of health (SOH) degradation acceleration rate of the battery cell; and
setting a reference value related to the SOH degradation acceleration rate used to determine a deterioration mode of the battery cell.

12. The battery diagnostic method of claim 11, further comprising:
setting the reference value related to the kinetic dispersion, based on a correlation between the SOH degradation acceleration rate and the kinetic dispersion.

13. The battery diagnostic method of claim 9, wherein determining the state of the battery cell includes:
determining a deterioration mode of the battery cell; and
diagnosing a possibility of a drop in a state of health (SOH) of the battery cell at or beyond a sharp drop point.

14. The battery diagnostic method of claim 13, wherein determining the state of the battery cell includes:
determining the deterioration mode as a first deterioration mode in which SOH degradation of the battery cell accelerates at a first acceleration rate less than a predetermined reference acceleration rate, based on the determined kinetic dispersion being less than the predetermined reference value related to the kinetic dispersion, and diagnosing that the possibility of the drop is small; and
determining the deterioration mode as a second deterioration mode in which the SOH degradation of the battery cell accelerates at a second acceleration rate greater than or equal to the predetermined reference acceleration rate, based on the determined kinetic dispersion being greater than or equal to the predetermined reference value related to the kinetic dispersion, and diagnosing that the possibility of the drop is large.

15. The battery diagnostic method of claim 9, wherein determining the state of the battery cell includes:
diagnosing whether the battery cell, an SOH of which is less than or equal to a certain value, is a reusable target or a recycle target.

16. The battery diagnostic method of claim 15, wherein determining the state of the battery cell includes:
diagnosing that the battery cell is the reusable target, based on the determined kinetic dispersion being less than the predetermined reference value related to the kinetic dispersion; and
diagnosing that the battery cell is the recycle target, based on the determined kinetic dispersion being greater than or equal to the predetermined reference value related to the kinetic dispersion.
